(19) United States
(12) Patent Application Publication
(10) Pub. No.: US 2026/0171682 A1
(43) Pub. Date: Jun. 18, 2026

(54) POLARIZABLE ANTENNA UNIT

(71) Applicant: Sennheiser electronic SE & Co. KG, Wedemark (DE)

(72) Inventors: Frank Plath, Wedemark (DE); Minh Tuan Nguyen, Laatzen (DE)

(73) Assignee: Sennheiser electronic SE & Co. KG, Wedemark (DE)

(21) Appl. No.: 19/420,906

(22) Filed: Dec. 16, 2025

(30) Foreign Application Priority Data
Dec. 17, 2024 (DE) 102024138178.7

(51) Int. Cl. H01Q 25/00; H01Q 15/24; H05K 1/03

(52) U.S. Cl. CPC H01Q 25/001; H01Q 15/24; H05K 1/0393

(57) ABSTRACT

A polarizable antenna unit comprising a first printed circuit board with at least one first electrical conductor and a second printed circuit board with at least one second electrical conductor. The second printed circuit board has at least one first printed circuit board part, which is configured to be partially pivotable. The first and second printed circuit boards are arranged at a printed circuit board angle to each other. In a first operating mode, the at least one first printed circuit board part has a first operating position with a first printed circuit board angle, in which the antenna unit has a first width. In a second operating mode, the at least one first printed circuit board part has a second operating position with a second printed circuit board angle, in which the antenna unit has a second width.

### RELATED APPLICATIONS

This application claims priority under 35 U.S.C. § 119(a) to German Patent Application No. 102024138178.7, filed Dec. 17, 2024, the disclosure of which is herein incorporated by reference in its entirety.

### FIELD

The present disclosure relates to a polarizable antenna unit.

### BACKGROUND

Polarized antennae such as, for example, a circularly polarized antenna or a double-polarized antenna, are known for radio applications, for example, in wireless transmission systems such as wireless microphone systems. Circularly polarized antennae are used to enable more stable and less interference-prone wireless transmission.

### SUMMARY

In some embodiments, a polarizable antenna unit comprises a first printed circuit board with at least one first electrical conductor, and a second printed circuit board with at least one second electrical conductor. In some embodiments, the second printed circuit board has at least one first printed circuit board part which is configured to be partially hinged or pivotable. In some embodiments, the first and second printed circuit boards are arranged at a printed circuit board angle to each other. In some embodiments, in a first operating mode the at least one first printed circuit board part of the second printed circuit board has a first operating position with a first printed circuit board angle, in which the antenna unit has a first width. In some embodiments, in a second operating mode the at least one first printed circuit board part of the second printed circuit board has a second operating position with a second printed circuit board angle, in which the antenna unit has a second width. In some embodiments, the first printed circuit board angle is larger than the second printed circuit board angle and the second width) is smaller than the first width of the antenna unit.

It should be appreciated that the foregoing concepts, and additional concepts discussed below, may be arranged in any suitable combination, as the present disclosure is not limited in this respect. Further, other advantages and novel features of the present disclosure will become apparent from the following detailed description of various non-limiting embodiments when considered in conjunction with the accompanying figures.

### BRIEF DESCRIPTION OF DRAWINGS

In the drawings, each identical or nearly identical component that is illustrated in various figures may be represented by a like numeral. For purposes of clarity, not every component may be labeled in every drawing. In the drawings:

FIG. 1 shows a perspective view of an antenna unit according to one embodiment;

FIG. 2 shows another perspective view of the antenna unit from FIG. 1;

FIG. 3A shows a plan view of the antenna unit of FIG. 1;

FIG. 3B shows an enlarged section of the plan view of FIG. 3A;

FIG. 4 shows a side view of the antenna unit of FIG. 1;

FIG. 5 shows another side view of the antenna unit from FIG. 1;

FIG. 6 shows a rear view of the antenna unit of FIG. 1;

FIG. 7 shows a perspective view of the antenna unit of FIG. 1 in a second operating position;

FIG. 8 shows another view of the antenna unit of FIG. 1 in the second operating position (transport position);

FIG. 9 shows a schematic view of a phase shifter for the antenna unit of FIG. 1;

FIG. 10 shows a plan view of another antenna unit according to one embodiment;

FIG. 11 shows a plan view of the antenna unit of FIG. 10;

FIG. 12 shows a rear view of the antenna unit of FIG. 10;

FIG. 13 shows another perspective view of the antenna unit from FIG. 10;

FIG. 14 shows another perspective view of the antenna unit of FIG. 10 in a second operating position; and

FIG. 15 shows a rear view of the antenna unit of FIG. 10 in a second operating position.

### DETAILED DESCRIPTION

In wireless microphone systems it is also known to use a helical antenna which is circularly polarized. A helical antenna is known from U.S. Pat. No. 8,780,009.

However, a disadvantage of the known antenna is that it does not allow for equivalent antennae for a horizontal polarization and a vertical polarization. Helical antennae also have reduced durability since they can be deformed for transport.

In the priority application of this application, the German Patent and Trademark Office has searched the following documents: EP 3 269 007 B1, EP 2 835 865 B1, DE 93 08 169 U1, DE 11 2013 004 923 T5 and U.S. Pat. No. 8,780,009 B2.

It is therefore an object of the present disclosure to provide a polarizable antenna which at least partially overcomes the disadvantages described above. In particular, it is an object of the present disclosure to provide a polarizable antenna which enables robust and stable radio transmission. Furthermore, it is an object of the present disclosure to provide a polarized antenna which has improved handling and is easy to transport.

This object is solved by a polarizable antenna according to Claim 1 and/or other embodiments disclosed herein.

In some embodiments, the polarizable antenna unit may comprise a first printed circuit board with a first electrical conductor and a second printed circuit board with a second electrical conductor. The second printed circuit board may comprise at least one first and one second printed circuit board part, which are configured to be at least partially tiltable or pivotable. The first and second printed circuit boards may be arranged at a printed circuit board angle of, for example, greater than 45° and, in particular, approximately 90° to each other, in order to allow for two polarizations. In some embodiments, in a first operating mode, the at least one printed circuit board part may have a first operating position with a first printed circuit board angle, in which the antenna unit has a first width. In a second operating mode, the at least one printed circuit board part may have a second operating position with a second printed circuit board angle, in which the antenna unit has a second width. In some embodiments, the first printed circuit board angle is greater than the second printed circuit board angle, and the first width is greater than the second width. An antenna unit is thus provided in some embodiments which has hinged or pivotable printed circuit boards to reduce the width of the antenna, for example, for transport.

According to one example embodiment, the first operating mode is a normal operating mode, in which the antenna unit can transmit and/or receive high-frequency signals. The second operating mode is a transport operating mode, in which the width of the antenna can be reduced by folding down a portion of the second circuit board. In the first operating mode, the two antenna circuit boards can be arranged at a 90° angle to each other, for example, to allow for a three-dimensional configuration. For transport (second operating mode), the printed circuit boards can be folded so that the antenna unit becomes more compact and fits easily into a music rack and can thus be transported. Thus, no further assembly of the antenna is required on site according to some embodiments. The antenna unit is unpacked, the printed circuit boards are folded from the transport position into an operating position, and the antenna unit is ready for use.

In some embodiments, in the first operating mode, the antenna unit may be active and may transmit and/or receive via the first and second circuit boards. In the second operating mode, the antenna unit may be inactive.

In some embodiments, in the first operating mode, the printed circuit board angle between the first and second circuit boards can be greater than 45°, and in particular approximately 90°, to create a three-dimensional antenna. In some embodiments, in the second operating mode (transport), the printed circuit board angle can be as small as possible and/or desired(e.g., less than 10°) to achieve compact (e.g., the most compact) transport dimensions.

According to one example, the second printed circuit board may have at least one first printed circuit board part. In the second operating mode, the at least one first printed circuit board part may be in the second operating position, so that the second width may be less than 50% of the first width.

According to one aspect, the second printed circuit board may have a central printed circuit board segment which is connected to the first printed circuit board. The second printed circuit board also may have the first and second printed circuit board parts, which are pivotably connected to the central circuit board segment, so that the first and second printed circuit board parts can each be pivoted into a first and second operating position with different antenna widths.

According to one aspect, the antenna unit may have at least two hinges, which are each coupled to the first and second printed circuit board parts to assist in pivoting the first and second printed circuit board parts.

According to another aspect, the second printed circuit board may be designed in the form of a rigid-flex printed circuit board.

According to another aspect, the first printed circuit board may have a first and a second printed circuit board section. In the first operating mode and in the first operating position of the second printed circuit board, the first and second printed circuit boards may intersect at a point of intersection. The first printed circuit board section may extend from the point of intersection in a first direction (e.g., upwards), and the second printed circuit board section may extend from the point of intersection in a second direction (e.g., downwards), which is opposite to the first direction. The first and second printed circuit board part of the second printed circuit board can be pivoted in the first or second direction.

According to one aspect, the printed circuit board section may have a first and second end as well as a height that increases from the first to the second end.

According to one aspect, the first printed circuit board section may have a plurality of ribs and printed circuit board slots.

In some embodiments, the polarizable antenna comprises a first printed circuit board with at least one first electrical conductor and a second printed circuit board with at least one second electrical conductor. The first and second printed circuit boards may be arranged at an angle to one another to allow for two polarizations. The second circuit board may be configured to be pivotable relative to the first printed circuit board, so that it is configured to be hinged relative to the first printed circuit board. In some embodiments, in a first operating mode (normal operating mode), the second printed circuit board is located in the unfolded state, i.e., the angle between the first and second printed circuit boards is substantially 90°. In the first operating mode, the second printed circuit board may be located in a first operating position and may be configured to be unfolded and may be configured to be substantially perpendicular to the first printed circuit board. In some embodiments, in a second operating mode, the second printed circuit board has a second operating position at least in part. In the second operating position, the second printed circuit board is configured to be folded or pivoted, so that the angle between the first and second printed circuit boards is less than 90°. The second operating position may be a transport position. This is particularly advantageous because the dimensions of the antenna can thereby be reduced. In the first operating position, the antenna can then be operated in a wireless transmission system.

In some embodiments, the second printed circuit board can be configured as a flexible printed circuit board or as a rigid-flex printed circuit board.

Optionally, in some embodiments, hinges can be attached to the second printed circuit board to allow the printed circuit board to swivel even over a longer service life. This can particularly improve the mechanical stability of the folding mechanism.

According to one example, in some embodiments, the printed circuit board may have a first and second end, as well as a first section above the hinges and a second section below the hinges. The first printed circuit board section may have a height that increases from the first to the second end. Therefore, the height of the first section of the first printed circuit board may be greater at the second end than at the first end.

According to one example embodiment, the first section has slots that extend substantially continuously in relation to the first section.

According to one example embodiment, the second printed circuit board section of the first printed circuit board may be configured to be substantially continuous.

Optionally, in some embodiments, the second printed circuit board may have a first and second printed circuit board part, each of which can be connected to the first printed circuit board via hinges. The first and second printed circuit board sections can be folded from a substantially vertical position by means of the hinges, so that the dimensions of the antenna are substantially reduced.

In some embodiments, the first printed circuit board section may have ribs that protrude from a plane formed by the second printed circuit board in the first operating position.

Thus, in some embodiments, an antenna unit can be formed with a first vertical antenna (first printed circuit board) and a horizontal antenna (second printed circuit board).

In some embodiments, a central printed circuit board section can be provided in the transition region between the first and second printed circuit boards. The central printed circuit board section can be part of the second printed circuit board or alternatively, it can be a separate printed circuit board.

Further embodiments of the present disclosure are the subject of the dependent claims.

Advantages and example embodiments according to the present disclosure are explained in more detail hereinafter with reference to the figures.

Turning to the figures, specific non-limiting embodiments are described in further detail. It should be understood that the various systems, components, features, and methods described relative to these embodiments may be used either individually and/or in any desired combination as the disclosure is not limited to only the specific embodiments described herein.

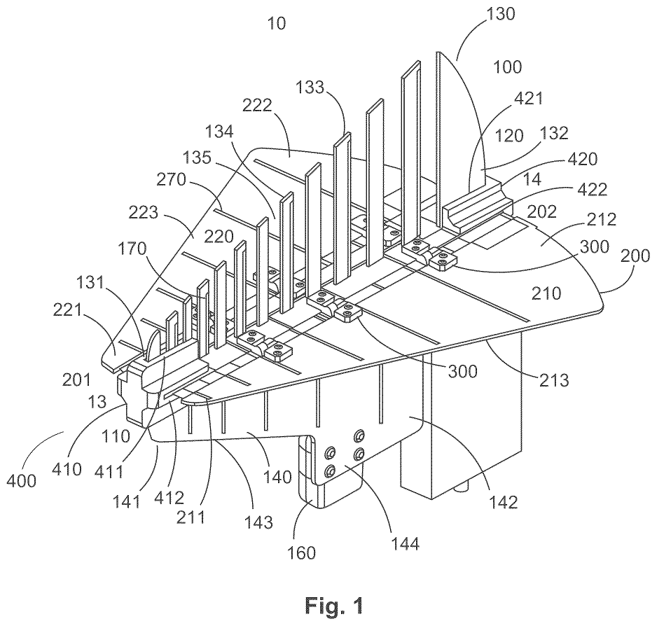

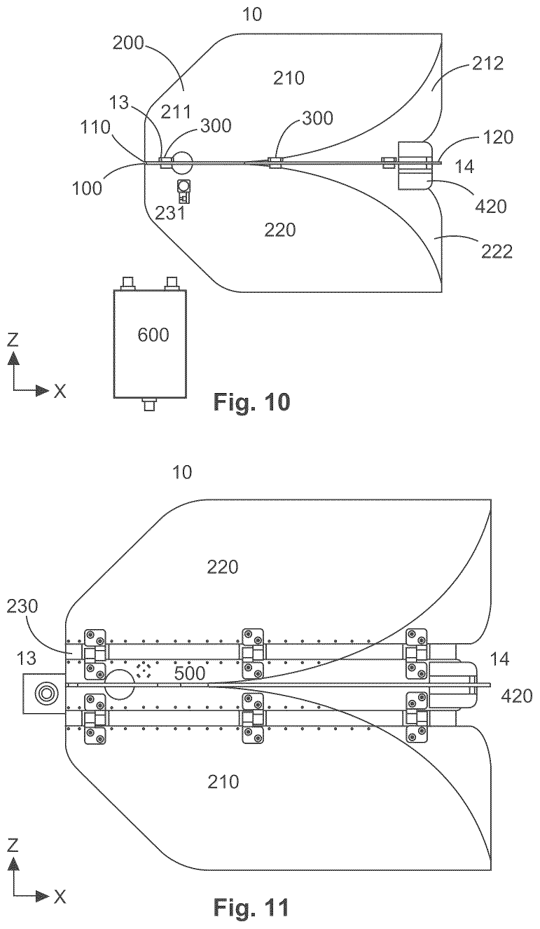

FIGS. 1 to 9 describe a first antenna unit, and FIGS. 10 to 16 describe a second antenna unit according to some embodiments. In some embodiments, the first antenna unit can be configured as a circularly polarizable log-periodic antenna (LPDA). In some embodiments, the second antenna unit can be configured as a circularly polarized Vivaldi antenna unit.

In some embodiments, in both antenna units a first printed circuit board having a first orientation and a second printed circuit board having a second orientation are provided. In a first operating mode, the second printed circuit board may have a first operating position, and in a second operating mode, the second printed circuit board may have a second operating position (transport). In some embodiments, the first printed circuit board does not change its operating position. In some embodiments, the first printed circuit board has at least one first electrical conductor, and the second printed circuit board has at least one second electrical conductor. In some embodiments, in the first operating mode, the second printed circuit board is arranged substantially perpendicular to the first printed circuit board. In the assembled state, the first printed circuit board can be configured to be vertical and the second printed circuit board can be configured to be horizontal in the first operating mode. In some embodiments, in the second operating mode, the first printed circuit board does not change its orientation, whilst the second printed circuit board is not oriented perpendicular to the first printed circuit board and is, for example, arranged at an angle of less than 45° to the first printed circuit board. In particular, the angle between the first and second printed circuit board in the second operating mode, i.e., in the second operating position of the second printed circuit board, can be <20°, in particular less than 10° according to some embodiments.

In some embodiments, in the first operating mode (first operating position), the antenna unit has a first width (i.e., a width or extent of the second circuit board), and in the second operating mode (second operating position), the antenna unit has a second width (i.e., a width or extent of the second printed circuit board). In some embodiments, the second width is smaller than the first width.

In some embodiments, the first printed circuit board can be configured as a rigid printed circuit board. The first and/or second printed circuit board can be electrically connected to an antenna connector.

In some embodiments, the first operating mode can be a normal operating mode in which the antenna is used as a transmitter and/or receiver in a wireless transmission system. In some embodiments, the second operating mode can be a transport mode in which the second printed circuit boards are folded in such a way that the width of the antenna unit is substantially reduced, whilst the height of the antenna unit remains substantially the same. In the second operating position (e.g., the second printed circuit board folded in), the antenna unit can be used for transport.

In some embodiments, the first antenna unit is a log-periodic dipole antenna (LPDA), also known for short as a logper. This is considered to be a broadband antenna and consists of a number of dipole antennae whose length and spacing decrease towards the direction of radiation and which are linearly polarized. In some embodiments, by connecting the two antenna printed circuit boards via a 90° hybrid coupler, the antenna unit can be circularly polarized. In some embodiments, the second antenna unit is designated as a Vivaldi antenna. Like the logper antenna, this is also broadband and linearly polarized. By connecting the two antenna printed circuit boards via a 90° hybrid coupler according to some embodiments, the antenna unit can be circularly polarized.

FIG. 1 shows a perspective view of an antenna unit according to an example embodiment. In the depicted embodiment, the antenna unit 10 has a first and second antenna end 13, 14 and a first and second printed circuit board 100, 200, which has a first and a second electrical conductor 170, 270. The second printed circuit board 200 is designed to be able to pivot or fold relative to the first printed circuit board 100 via hinges 300. The first printed circuit board 100 has a first and second end 110, 120 as well as a first printed circuit board section 130 and a second printed circuit board section 140. The first printed circuit board section 130 has a first and second end 131, 132 and a height 133, which increases from the first to the second end 110, 120. In some embodiments, the first printed circuit board section 130 can have a plurality of ribs 134 and slots 135 between them. The first printed circuit board section 130 can also be configured throughout without ribs or slots.

In the depicted embodiment, the second printed circuit board section 140 has a first and second end 141, 142, and a varying height 143. The second printed circuit board section 140 has a mounting 144 for a mechanical mounting unit 160, by means of which the antenna unit 10 can be attached. In some embodiments, an electrical antenna connection 150 can be provided in the region of the second end 142 of the second printed circuit board section 140. In some embodiments, the electrical antenna connection 150 is electrically connected to the electrical conductors 170 in the first printed circuit board 100. In the depicted embodiment, a further electrical antenna connection 151 is provided for the second printed circuit board, which is electrically connected to the electrical conductors 270 in the second printed circuit board 200. The two printed circuit boards, 100 and 200, can thus be controlled via separate connections. The circuit boards can thus also be used as separate antennae. Furthermore, in some embodiments, only one of the two antennae and/or both in combination can be used.

In the depicted embodiment, the second printed circuit board 200 has a first and second printed circuit board part 210, 220, each of which is configured to be able to be tilted or folded via hinges 300. The first printed circuit board part 210 and the second printed circuit board part 220 are electrically connected to each other and have the second electrical conductor.

In the depicted embodiment, the first printed circuit board part 210 and the second printed circuit board part 220 have at least in sections a flexible or rigid-flex printed circuit board. In particular, in the area of the hinges 300, the second printed circuit board 200 is configured as a flexible printed circuit board so that the first and second printed circuit board parts 210, 220 can be folded from a first operating position (substantially perpendicular to the first printed circuit board) into a second operating position in which the angle between the first and second printed circuit boards is less than 20°.

In some embodiments, the second printed circuit board 200 can have a central circuit board segment 500, to which the first and second printed circuit board parts 210, 220 can be coupled via hinges 300.

In some embodiments, in a first operating mode, the second printed circuit board 200 is in a first operating position, so that the antenna unit 10 can be operated in a wireless audio transmission system.

In some embodiments, in a second operating mode, the first and second printed circuit board parts 210, 220 are located in a second operating position, so that the antenna unit 10 can be easily trans-ported due to its smaller dimensions.

In the depicted embodiment, the second printed circuit board 200 has a first and second end 201, 202. The first printed circuit board part 210 has a first and second end 211, 212. The second printed circuit board part 220 has a first and second end 221, 222. Furthermore, the first printed circuit board part 210 has a width 213 and the second printed circuit board part has a width 223. The widths 213, 223 of the first and second circuit board parts increase from the first end 211, 221 to the second end 212, 222.

In some embodiments, a printed circuit board mounting 400 can be provided for fastening the first and second printed circuit boards 100, 200, which has a first and second printed circuit board mounting element 410, 420. The first and second printed circuit board mounting elements 410, 420 may each have vertical mounting slots 411, 421 and horizontal mounting slots 412, 422, which serve to accommodate the first or second printed circuit board 100, 200.

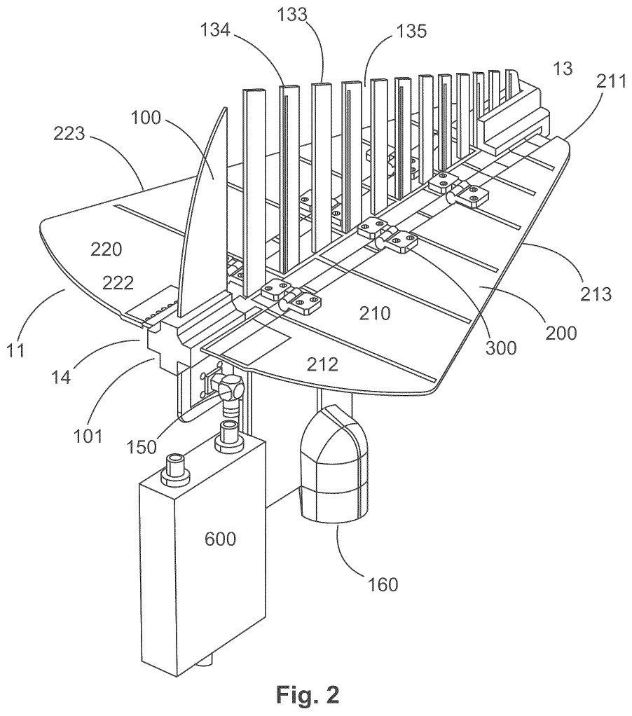

FIG. 2 shows another perspective view of the antenna from FIG. 1. Whilst FIG. 1 shows the view from the first end of the antenna unit, FIG. 2 shows the perspective view from the second end of the antenna unit. In the depicted embodiment. the antenna unit is located in the first operating mode, and the second printed circuit board parts 210, 220 are located in the first operating position. A phase shifter 600 is also shown.

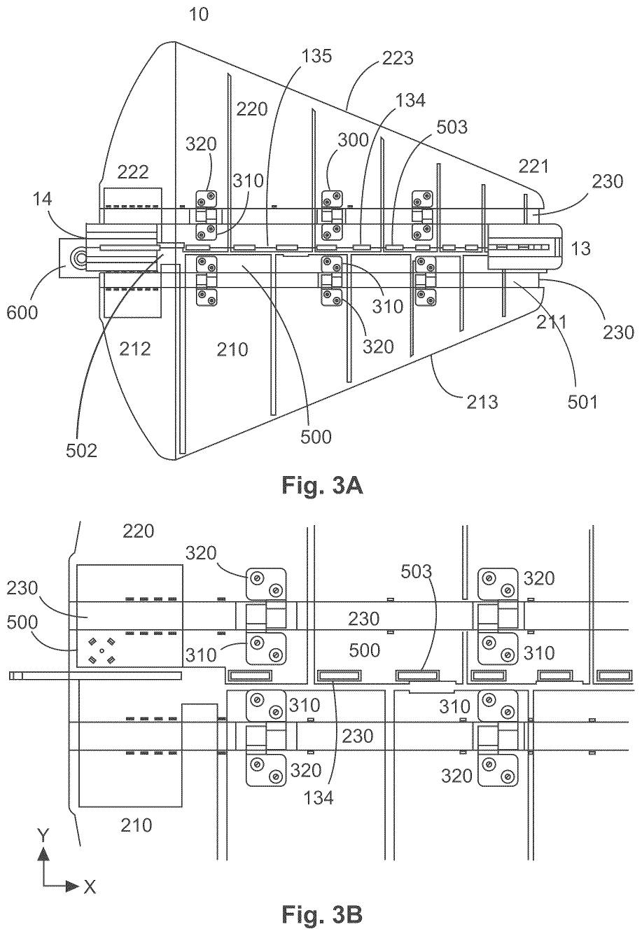

FIG. 3A shows a plan view of the antenna unit from FIG. 1 and FIG. 3B shows an enlarged section of the plan view from FIG. 3A. In particular, the first and second printed circuit boards 100, 200, and the hinges 300 are shown. Here, the first hinge sections 310 are connected to a central printed circuit board section 500, and the second hinge sections 320 are each connected to a first or second printed circuit board part 210, 220. Six hinges 300 are shown in FIG. 3A. The number of hinges should be at least two although any number of hinges is contemplated as the disclosure is not so limited.

In some embodiments, the central printed circuit board section 500 can be configured as a separate printed circuit board or as part of the second printed circuit board. In the depicted embodiment, the central printed circuit board section 500 has a first and second end 501, 502, and optionally a plurality of holes 503, each for receiving the ribs 134 of the first printed circuit board 100. The hinges 300 each have a first and second hinge section 310, 320. The first hinge sections 310 are each connected to the central printed circuit board section 500, and the second hinge sections 320 are connected to the first or second printed circuit board part 210, 220. Flexible printed circuit board sections 230 are provided between the central printed circuit board section 500 and the first or second printed circuit board part 210, 220 to allow the first and second printed circuit board part 210, 220 to pivot.

Optionally, in some embodiments, only the first or second circuit board section 210, 220 can be configured to be pivotable, whilst the other printed circuit board part is not configured to be pivotable but is fixed.

In some embodiments, the second printed circuit board 200 can be configured as a rigid-flex printed circuit board with three rigid sections, namely the first printed circuit board part 210, the second printed circuit board part 220, and the central printed circuit board section 500, wherein a flexible printed circuit board section 230 can be provided between the first and second printed circuit board parts 210, 220 and the central printed circuit board section 500. Alternatively, in some embodiments, the printed circuit board 200 can have a separate central printed circuit board section 500 as well as first and second printed circuit board parts 210, 220, which are configured separately from the central printed circuit board section 500. In some embodiments, the first and second printed circuit board parts 210, 220 can be configured as a rigid-flex printed circuit board, wherein the flexible portion is configured as a flexible printed circuit board section 230. The flexible circuit board section 230 can then, for example, be electrically coupled to the central circuit board section 500 via connectors in some embodiments.

In some embodiments, the second printed circuit board 200 can therefore be configured as a printed circuit board or as a multi-part printed circuit board.

In some embodiments, the first printed circuit board 100 is preferably configured as a continuous printed circuit board with a first and second section 130, 140. Alternatively, in some embodiments, the first printed circuit board 100 can also be configured as multi-part.

When assembling the first and second printed circuit boards 100, 200, the ribs 134 of the first printed circuit board 100 can be inserted into the holes or openings 503 in some embodiments. Using the printed circuit board mounting 400 with the first and second printed circuit board mounting elements 410, 420, the first and second printed circuit boards 100, 200 can be fastened together and/or to each other.

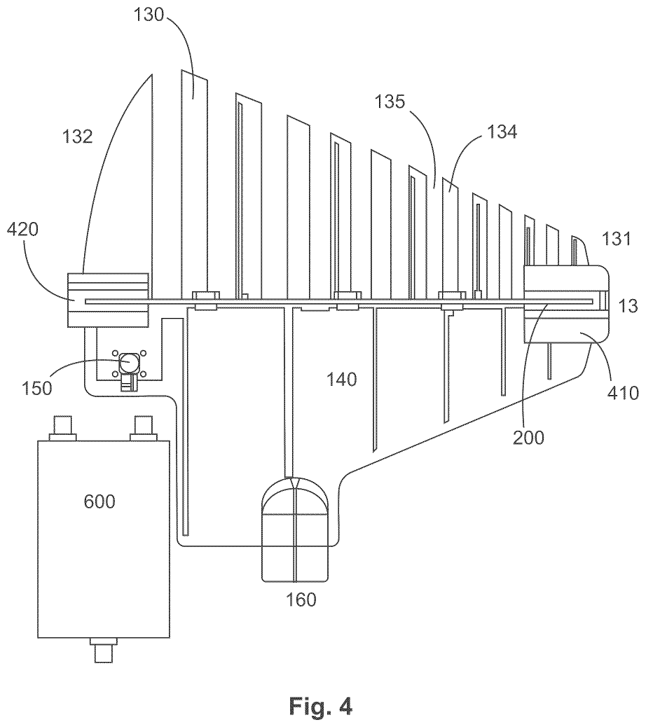

FIG. 4 shows a side view of the antenna unit of FIG. 1.

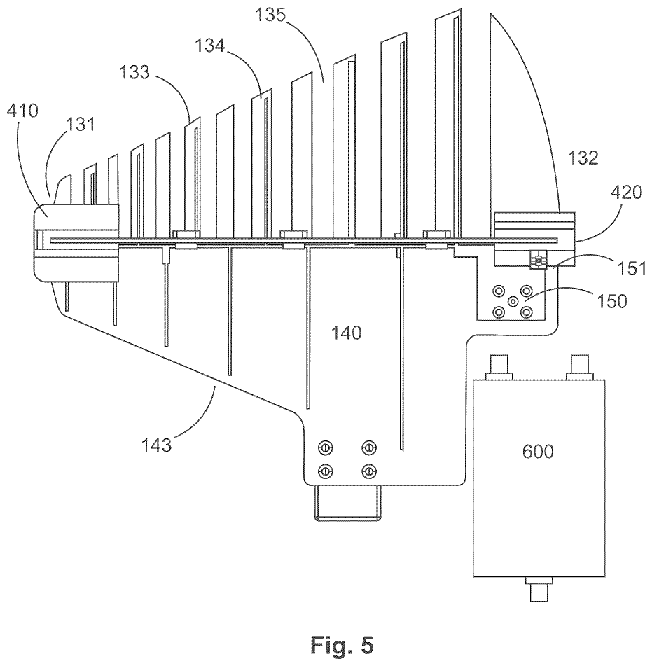

FIG. 5 shows a side view of the antenna unit of FIG. 1.

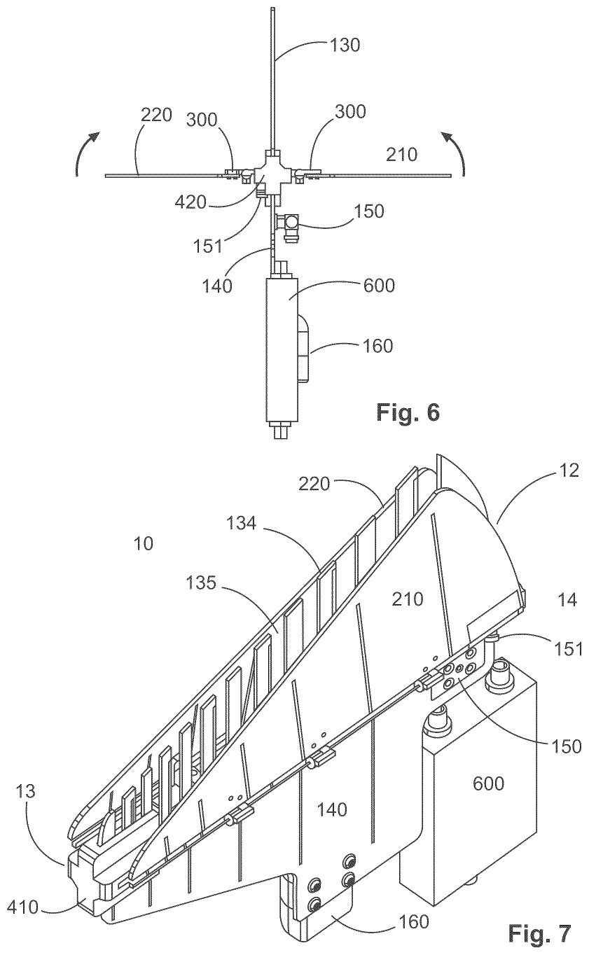

FIG. 6 shows a plan view of an antenna unit from FIG. 1. In the embodiments of FIGS. 4 to 6, the antenna unit is shown in the first operating mode, with the printed circuit board parts 210, 220 being shown in the first operating position (substantially perpendicular to the first printed circuit board).

FIG. 7 shows a perspective view of the antenna unit of FIG. 1 in a second operating mode.

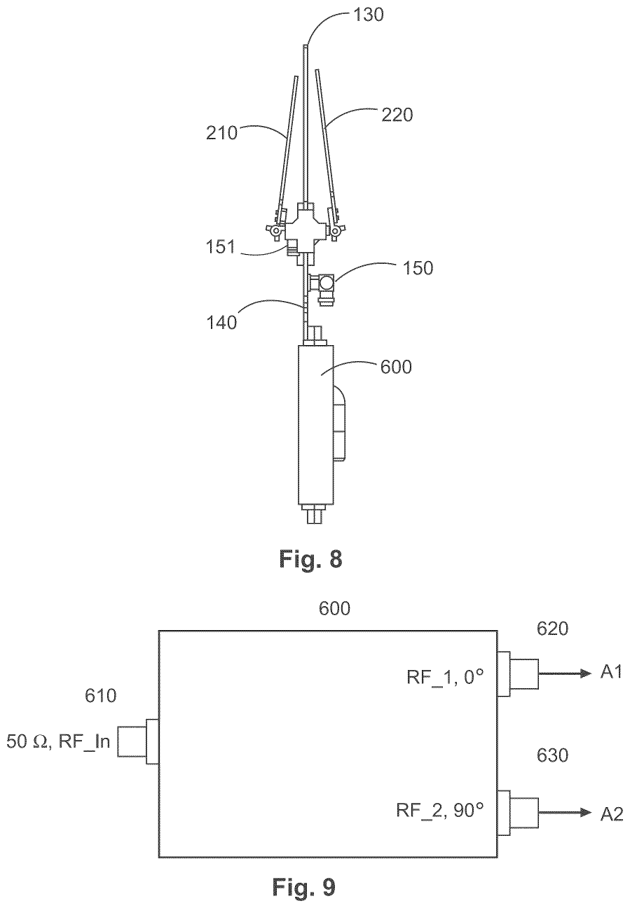

FIG. 8 shows a plan view of the antenna unit of FIG. 1 in a second operating mode.

The operating mode shown in the embodiments of FIGS. 7 and 8 (e.g., transport mode) comprises the second printed circuit board parts 210, 220 located in a second operating position, i.e., the angle between the first printed circuit board and the first and second printed circuit board parts is less than 10° in order to obtain the flattest possible antenna unit for transport. In particular, the first and second printed circuit board parts are located in the folded state so that the width of the antenna unit can be reduced to allow transport of the antenna unit, for example, in a suitcase. Of course, any desired angle between the first and second printed circuit board parts can be used as the disclosure is not so limited.

FIG. 9 shows a schematic view of a phase shifter 600 with one input 610 and two phase shifter outputs 620, 630 according to some embodiments. In the embodiment, an RF input signal is present at the input 610. An RF output signal A1 at 0° is present at the first phase shifter output 620, and an RF output signal A2 at 90° is present at the second phase shifter output 630. The first output signal A1 is connected, for example, to the first printed circuit board 100 via the first antenna connection 150, and the second output signal A1 at the second phase shifter output 630 is connected, for example, to the second circuit board 200 via the second antenna connection 151. This enables circular polarization of the antenna unit via the first and second printed circuit boards 100, 200. Thus, in some embodiments, a signal with a 90° phase shift can be applied to the first printed circuit board, and the signal without a phase shift (0°) is applied to the second printed circuit board. This is made possible by the fact that the first and second printed circuit boards each have their own antenna connection according to some embodiments.

FIGS. 10 to 16 show an alternative antenna unit according to some embodiments.

FIG. 10 shows a plan view of another antenna unit according to one embodiment and FIG. 11 shows a plan view of the antenna unit from FIG. 10. The antenna unit 10 has a first and second printed circuit board 100, 200. In some embodiments, the first printed circuit board 100 can be configured as a rigid printed circuit board with a first plane. In the depicted embodiment, the second printed circuit board 200 has a first and second printed circuit board part 210, 220, each of which is connected to a central section via hinges 300, so that they are pivotable.

The antenna unit 10 in the depicted embodiment has a first and second end 13, 14. The first printed circuit board 100 has a first and second end 110, 120. The first printed circuit board part 210 has a first and second end 211, 212. The second printed circuit board part 220 has a first and second end 221, 222. In the example of FIG. 10, the first printed circuit board 100 is continuous and does not have ribs and slots as shown in FIG. 1.

In some embodiments, the second printed circuit board 200 can have a central printed circuit board segment 500 and a first and second printed circuit board part 210, 220. A flexible printed circuit board section 230 can be provided between the central printed circuit board segment 500 and the first and second printed circuit board parts 210, 220 to allow the first and second printed circuit board parts 210, 220 to pivot.

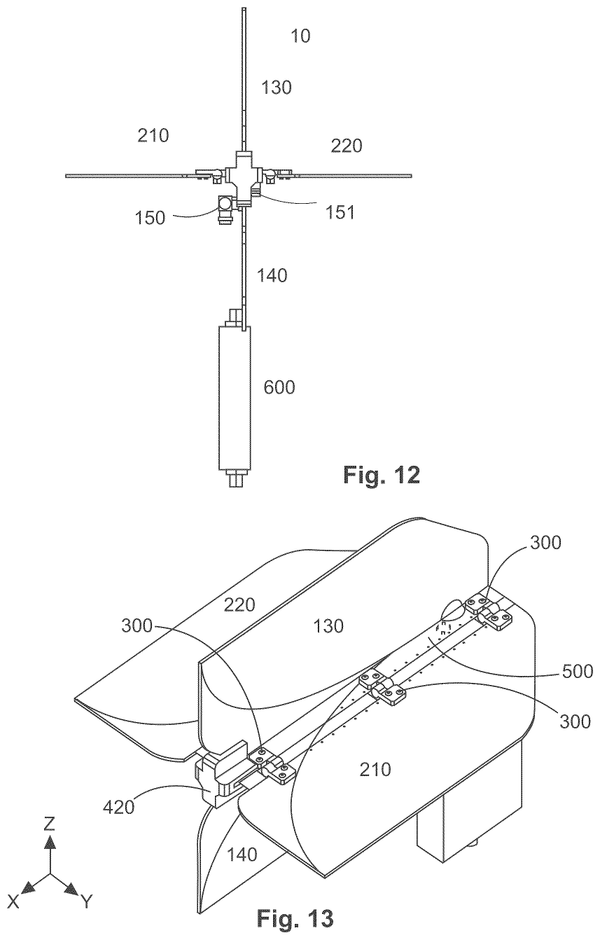

FIG. 12 shows another view of the antenna from FIG. 10. FIG. 13 shows another perspective view of the antenna unit from FIG. 10.

FIGS. 10 to 12 show the antenna unit in a first operating mode, with the second printed circuit board parts arranged in a first operating position. In the first operating position, the first and second printed circuit board parts are arranged substantially perpendicular to the first printed circuit board.

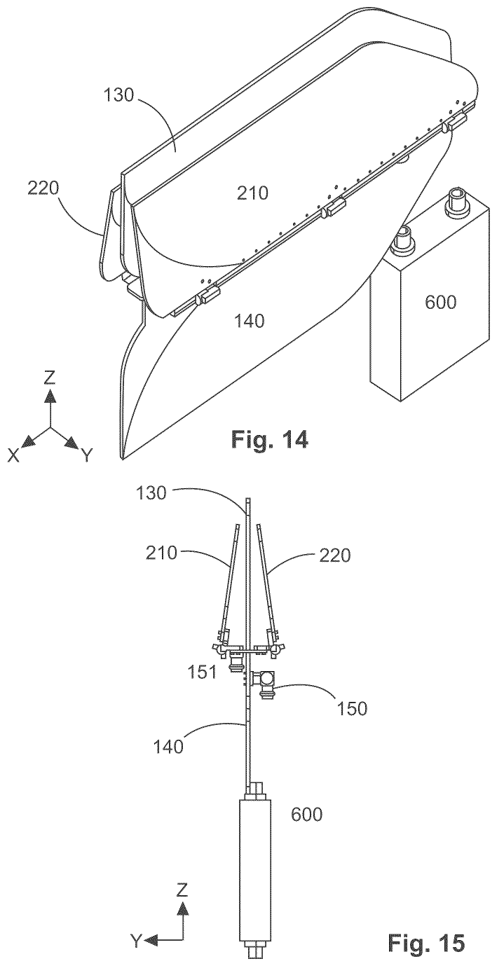

FIGS. 14 and 15 show the antenna unit in a second operating mode, with the second printed circuit board parts 210, 220 located in a second operating position.

In some embodiments, the first and second antenna units can, for example, be operated at a frequency between 470 MHz and 1.8 GHz. Alternatively, in some embodiments, the first and second antennae can also be operated at a Bluetooth communication frequency of approximately 2.5 GHz.

In some embodiments, the first antenna unit of FIG. 1 can, for example, have a length of 334 mm and a width of 293.4 mm. In particular, in some embodiments, the length of the antenna unit can be between 300 and 400 mm and the width can be between 200 and 400 mm.

In some embodiments, the second antenna unit can have a length of between 250 and 350 mm, in particular 310 mm. In some embodiments, the width of the antenna unit (in the first operating mode) can, for example, be between 200 and 300 mm, in particular 262 mm.

In some embodiments, the antenna unit described above can be used as a dual antenna for polarization diversity, for example as a microphone receiver, or with a phase shifter 600 as a circularly polarized antenna. In some embodiments, the antenna inputs can comprise an RF socket.

The antenna unit can be configured as a broadband log-periodic antenna or a Vivaldi antenna.

The antenna unit can be used both as a diversity antenna for two orthogonal polarizations for one antenna position and as a circularly polarized antenna with a 90-degree phase shifter connected thereto.

Due to the foldability of the second circuit board, the antenna unit can be easily transported, for example in a music rack.

In some embodiments, the antenna comprises at least two printed circuit boards, wherein one printed circuit board is a rigid printed circuit board. The first rigid printed circuit board can accommodate antenna elements of the vertical broadband antenna. In some embodiments, the second printed circuit board can be configured as a rigid-flex printed circuit board, which can accommodate the antenna elements of the horizontal antenna structure. Additionally, in some embodiments, a third printed circuit board can be provided, which comprises an optional broadband 90° phase shifter for horizontal or vertical polarization, and thus makes it possible to use a dual-polarized antenna as a circular antenna.

In some embodiments, the phase shifter can be arranged on the first or second printed circuit board. The antenna unit can be used as a log-periodic antenna or as a Vivaldi antenna.

In some embodiments, the antenna structures on the first and second printed circuit boards can comprise both a feed line and antenna elements.

In some embodiments, slots or recesses can optionally be provided in the first printed circuit board so that the horizontal antenna and the vertical antenna can be plugged into each other. In some embodiments, the vertical antenna can be made from a rigid printed circuit board, whilst the horizontal antenna (second printed circuit board) can be made from a combination of rigid and flexible printed circuit board sections.

In some embodiments, the antenna structures of the rigid and flexible segments can be connected via vias. In some embodiments, the flexible area of the printed circuit board may also allow frequent folding of the second printed circuit boards without damage. For this purpose, additional hinges can be used in some embodiments to mechanically connect the rigid printed circuit board sections (e.g., made of non-conductive material, plastic, etc.). Optionally, in some embodiments, the hinges can have a mechanical stop to limit the folding angle. In some embodiments, the hinges can also have locking tabs that allow the printed circuit boards to be fixed in the 90° or 180° position.

The antenna unit according to the embodiments of FIGS. 10 to 16 can have Vivaldi structures for the horizontal and vertical antennae (first and second printed circuit boards). In particular here, a horizontal slot is provided in both circuit boards for interlocking. Optionally, in some embodiments, a 90° phase shift can be provided on an additional printed circuit board or on the first and second printed circuit boards.

In some embodiments, a central part of the second printed circuit board (horizontal printed circuit board) has a supply line. This central part of the second printed circuit board may be connected to the first printed circuit board at a 90° angle. In some embodiments, the first and second printed circuit board parts 210, 220 are connected to the central section via flexible printed circuit boards and hinges. Furthermore, in some embodiments, a mounting adapter for receiving commercially available microphone clips or mounting clamps is provided on the first printed circuit board.

The antenna unit according to the embodiments of FIGS. 1 to 9 can be a circularly polarized antenna, which transmits or receives electromagnetic waves in circular polarization. In circular polarization, the electric and magnetic field vectors of the wave rotate in a spiral motion about the direction of propagation. A circularly polarized wave is advantageous because it is less susceptible to signal loss due to reflections or multipath interference. Furthermore, it enables improved communication even if the transmitter and the receiver are not precisely aligned, which is particularly advantageous for moving transmitters or receivers.

In some embodiments, the second antenna unit can be configured as a Vivaldi antenna. A Vivaldi antenna is a broadband antenna with a very high bandwidth and directivity. The Vivaldi antenna has a narrow, scoop-or funnel-shaped element that widens outwards along a logarithmically periodic pattern. Due to this shape the antenna unit can receive or transmit signals over a wide frequency range.

In some embodiments, the antenna unit can be folded for transport. When assembling for operation as intended, it may therefore be necessary in some embodiments to unfold the second printed circuit board and transfer the antenna unit from the transport operating mode to the normal operating mode. It is therefore possible that a user omits to unfold the antenna unit during assembly. If the antenna unit is put into operation in the folded-up state, in a typical application it should be assumed that a wireless transmission of signals can take place nevertheless but the range and the transmission quality may be limited compared to the unfolded state. In order to counteract this scenario, in some embodiments, measures can be optionally taken by means of which this situation is identified and the user is informed so that he can subsequently unfold the antenna unit. Optionally, in some embodiments, a contact unit can be provided for this purpose at a fold point whose contact state can be read via a supply line. In the unfolded state of the antenna unit (e.g., normal operating mode), the contact unit may have a different state from the folded antenna unit (e.g., transport operating mode) so that the device connected to the contact unit via the supply line can identify whether the antenna is unfolded and can output an error message to the user if it is in the folded state. Alternatively, in some embodiments, the folding state of the antenna unit can be checked via the first antenna connector 150 and the second antenna connector 151. A transmission signal may be sent to one of the two antenna connectors 150 or 151 and receipt of this signal may be measured at the other of the two antenna connectors. If the antenna unit is unfolded in the normal operating mode, as a result of the orthogonal arrangement of the first printed circuit board 100 with respect to the second printed circuit board 200, the received signal may have a smaller amplitude than if the antenna unit is located in the folded transport operating mode or at least is not completely unfolded. In some embodiments, a transmitting/receiving unit connected to the two antenna connectors 150 and 151 can execute this measurement procedure and output an error message to the user if the amplitude of the signal received exceeds a reference value.

### REFERENCE LIST

10 Antenna unit
11 First antenna width
12 Second antenna width
13 First antenna end
14 Second antenna end
100 First printed circuit board
103 Printed circuit board height
105 First electrical conductor
110 First end
120 Second end
130 First printed circuit board section
131 First end
132 Second end
133 Height
134 Ribs
135 Slots
140 Second printed circuit board section
141 First end
142 Second end
143 Height
144 Mounting
150 First antenna connection
151 Second antenna connection
160 Mounting unit
170 First electrical conductor
200 Second circuit board
201 First end
202 Second end
203 First printed circuit board width
204 Second printed circuit board width
205 Second electrical conductor
210 First printed circuit board part
211 First end
212 Second end
213 Width
220 Second printed circuit board part
221 First end
222 Second end
223 Width
230 Flex sections
270 Second electrical conductor
300 Hinges
310 First hinge section
320 Second hinge section
400 Printed circuit board mounting
410 First printed circuit board mounting element
411 First vertical mounting slot
412 First horizontal mounting slot
420 Second printed circuit board mounting element
421 Second vertical mounting slot
422 Second horizontal mounting slot
500 Central printed circuit board segment
501 First end
502 Second end
503 Holes
600 Phase shifters
620 First output
630 Second output
A1 First phase shifter output signal
A2 First phase shifter output signal

Various aspects of the embodiments described above may be used alone, in combination, or in a variety of arrangements not specifically discussed in the embodiments described in the foregoing and are therefore not limited in their applications to the details and arrangement of components set forth in the foregoing description or illustrated in the drawings. For example, aspects described in one embodiment may be combined in any manner with aspects described in other embodiments.

The phrase “and/or,” as used herein in the specification and in the claims, should be understood to mean “either or both,” of the elements so conjoined, e.g., elements that are conjunctively present in some cases and disjunctively present in other cases. Multiple elements listed with “and/or” should be construed in the same fashion, e.g., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

The indefinite articles “a” and “an,” as used herein in the specification and in the claims, unless clearly indicated to the contrary, should be understood to mean “at least one.”

As used herein in the specification and in the claims, the phrase, “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently, “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

All definitions, as defined and used herein, should be understood to control over dictionary definitions, definitions in documents incorporated by reference, and/or ordinary meanings of the defined terms.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the scope of the principles described herein. Accordingly, the foregoing description and drawings are by way of example only.

What is claimed is:

1. A polarizable antenna unit, comprising
a first printed circuit board with at least one first electrical conductor, and a
second printed circuit board with at least one second electrical conductor,
wherein the second printed circuit board has at least one first printed circuit board part which is configured to be partially pivotable,
wherein the first and second printed circuit boards are arranged at a printed circuit board angle to each other,
wherein in a first operating mode the at least one first printed circuit board part of the second printed circuit board has a first operating position with a first printed circuit board angle, in which the antenna unit has a first width,
wherein in a second operating mode the at least one first printed circuit board part of the second printed circuit board has a second operating position with a second printed circuit board angle, in which the antenna unit has a second width,
wherein the first printed circuit board angle is larger than the second printed circuit board angle and the second width is smaller than the first width of the antenna unit.

2. The polarizable antenna unit according to claim 1, wherein the first operating mode is a normal operating mode in which the antenna unit transmits and/or receives high-frequency signals, wherein the second operating mode is a transport operating mode, wherein the first printed circuit board angle is greater than 45°, and wherein the second printed circuit board angle is less than 20°.

3. The polarizable antenna unit according to claim 1, wherein
the second printed circuit board has a first and a second printed circuit board part, and wherein in the second operating mode the first and second printed circuit board parts are each in the second operating position, so that the second width is less than 50% of the first width of the antenna unit.

4. The polarizable antenna unit according to claim 1, wherein the second printed circuit board has a central printed circuit board segment which is connected to the first printed circuit board, and wherein the first and the second printed circuit board parts are pivotably connected to the central printed circuit board segment, so that the first and second printed circuit board parts can each be pivoted into the first and second operating positions.

5. The polarizable antenna unit according to claim 1, further comprising:
at least two hinges which are each coupled to the first printed circuit board part and the second printed circuit board part to support pivoting of the first and second printed circuit board parts.

6. The polarizable antenna unit according to claim 1, wherein the second printed circuit board is configured as one of a flexible printed circuit board and a rigid-flex printed circuit board.

7. The polarizable antenna unit according to claim 1, wherein
the first printed circuit board has a first and second printed circuit board section, wherein in the first operating mode and in the first operating position of the second printed circuit board the first and second printed circuit boards intersect at an intersection point, wherein the first printed circuit board section extends from the intersection point in a first direction and the second printed circuit board section extends from the intersection point in a second direction, the second direction being opposite to the first direction, and wherein the first and second printed circuit board part of the second printed circuit board is pivotable in the first or second direction.

8. The polarizable antenna unit according to claim 7, wherein the first printed circuit board section has a first end and a second end and a height which increases from the first end to the second end.

9. The polarizable antenna unit according to claim 7, wherein the first printed circuit board section has a plurality of ribs and printed circuit board slots.

10. The polarizable antenna unit according to claim 1, wherein
the first printed circuit board has a first antenna connection and the second printed circuit board has a second antenna connection, so that different RF signals can be supplied to the first and second printed circuit boards.

11. The polarizable antenna unit according to claim 10, further comprising:
a phase shifter with an RF input for an RF input signal and a first and second phase shifter output, wherein the phase shifter outputs an RF output signal at 0° at one of the two phase shifter outputs and an RF output signal at 90° at the other phase shifter output,
wherein the first phase shifter output is coupled to the first or second antenna connection, and the second phase shifter output is coupled to the second or first antenna connection to obtain a circularly polarized antenna unit.
